(19) United States
(12) Patent Application Publication
(10) Pub. No.: US 2019/0159335 A1
(43) Pub. Date: May 23, 2019

(54) FLEXIBLE CIRCUIT BOARD AND DISPLAY PANEL

(71) Applicant: WUHAN CHINA STAR OPTOELECTRONICS SEMICONDUCTOR DISPLAY TECHNOLOGY CO., LTD., Wuhan, Hubei (CN)

(72) Inventor: Jia-Shu WU, Shenzhen, Guangdong (CN)

(21) Appl. No.: 15/744,222

(22) PCT Filed: Dec. 7, 2017
(86) PCT No.: PCT/CN2017/114930

§ 371 Date: May 1, 2018

(30) Foreign Application Priority Data
Nov. 20, 2017 (CN) 201711169904.7

(51) Int. Cl. H05K 1/02; H05K 1/03

(52) U.S. Cl. CPC H05K 1/0281; H01L 27/3276; H05K 2201/10128; H05K 1/0393

(57) ABSTRACT

This invention provides a flexible circuit board comprising a substrate and a protective layer, the protective layer being disposed on the substrate. The protective layer includes a glue layer, a first functional layer, and a second functional layer sequentially stacked on the substrate. The first functional layer comprises two or more first bending bands arranged at intervals. The two or more first bending bands extend in the same direction. The second functional layer comprises two or more second bending bands arranged at intervals. The two or more second bending bands extend in the same direction. The extending direction of the two or more first bending bands is disposed with an angle with the extending direction of the two or more second bending bands. By using the flexible circuit board provided by this invention, the strength thereof is improved, and it is effectively protected, in the meanwhile of more easily bending.

### RELATED APPLICATIONS

The present application is a National Phase of International Application Number PCT/CN2017/114930, filed Dec. 7, 2017, and claims the priority of China Application No. 201711169904.7, filed Nov. 20, 2017.

### FIELD OF THE DISCLOSURE

The present invention relates to a display technical field, and more particularly to a flexible circuit board and a display panel.

### BACKGROUND

In current design of a flexible AMOLED display panel, in order to achieve the purpose of a narrow frame, a flexible circuit board is bonded with a display panel and folded to reduce the length of the non-display area and achieve a high ratio of the screen occupation. However, the flexible circuit board is susceptible to micro cracks, circuit breaks or circuit stripping after bending, resulting in poor display of the flexible AMOLED display.

In the prior art, the photosensitive adhesive or the tapioca resin is coated on a bonding region and a bending region of the flexible circuit board to prevent defects caused by the flexible circuit board after being bent. However, uniformity of a large area coating is not easy to be controlled, the thickness of the coating is limited, its thickness is too thick to be bent, and the strength of glue is restricted.

### SUMMARY

The purpose of the present invention is to provide a flexible circuit board and a display panel that make the flexible circuit board easier to bend, prevent circuit from damage, improve the strength of the flexible circuit board, and make the flexible circuit board being effectively protected.

According to a first aspect of the present invention, there is provided a flexible circuit board comprising a substrate and a protective layer, the protective layer being disposed on the substrate. The protective layer includes a glue layer, a first functional layer, and a second functional layer sequentially stacked on the substrate. The first functional layer includes two or more first bending bands arranged at intervals. The two or more first bending bands extend in the same direction. The second functional layer includes two or more second bending bands arranged at intervals. The two or more second bending bands extend in the same direction. The extending direction of the two or more first bending bands is disposed with an angle with the extending direction of the two or more second bending bands.

The materials of the two or more first bending bands and the two or more second bending bands are flexible inorganic fiber material and/or flexible polymer.

The flexible inorganic fiber material comprises glass fiber, ceramic fiber or carbon fiber.

The flexible polymer includes PET, PMMA or non-woven fabric.

An angle formed by the extending direction of the first bending bands and the extending direction of the second bending bands ranges from 45° to 90°.

During a process of bending the flexible circuit board, the bending direction of the first bending bands or the bending direction of the second bending bands is the same as the bending direction of the substrate.

The substrate includes a bending region, and the protective layer is disposed on the bending region.

The substrate further includes a bonding region for bonding a panel. The area of the protection layer is larger than the area of the bending region. The protection layer extends from the bending region to the bonding region.

The number of the first functional layer and the number of the second functional layer are both at least two.

According to a second aspect of the present application, a display screen is provided, which includes the flexible circuit board provided in the first aspect of the present invention.

According to a flexible circuit board provided by the first aspect of the present invention, since a protective layer having a glue layer, a first function layer, and a second function layer is disposed on a substrate of a flexible circuit board, the first function layer and the second function layer replace a portion of a glue layer in the prior art. The thickness of the glue layer is thus reduced. Moreover, since the extending direction of the first bending bands and the extending direction of the second bending bands are set at an angle, the first bending band or the second bending band which are close to the bending direction promotes the bending of the flexible circuit board when the flexible circuit board is bent. Meanwhile, the other first bending band or second bending band serves to fix, protect and strengthen the flexible circuit board. The display panel provided by the second aspect of the present invention can make the flexible circuit board more flexible, avoid the circuit from damage, improve the strength of the flexible circuit board, make the flexible circuit board being effectively protected and improve the quality of the display panel.

### BRIEF DESCRIPTION OF THE DRAWINGS

Accompanying drawings are for providing further understanding of embodiments of the disclosure. The drawings form a part of the disclosure and are for illustrating the principle of the embodiments of the disclosure along with the literal description. Apparently, the drawings in the description below are merely some embodiments of the disclosure, a person skilled in the art can obtain other drawings according to these drawings without creative efforts. In the figures:

FIG. 1 is a schematic structural diagram of a flexible circuit board according to an embodiment of the present application; and

FIG. 2 is a schematic structural view of a protective layer in an embodiment of the present invention.

### DETAILED DESCRIPTION OF PREFERRED EMBODIMENTS

In order to understand the above objectives, features and advantages of the present disclosure more clearly, the present disclosure is described in detail below with references to the accompanying drawings and specific embodiments. However, it should be noted that the following is a preferred embodiment of the present application, and it should be noted that those skilled in the art may make various improvements and modifications without departing from the principle of the present disclosure which is the protection scope of the present application.

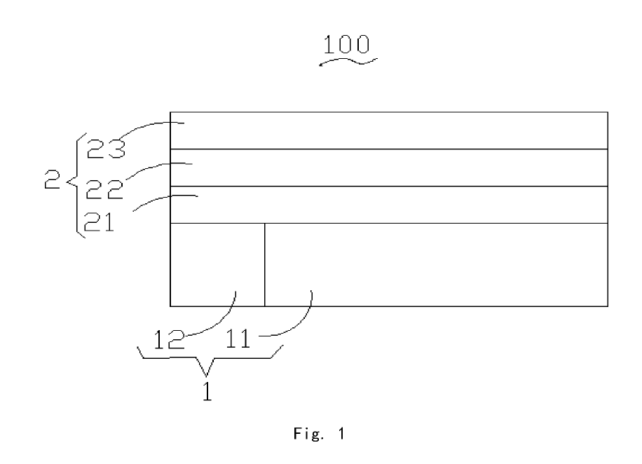

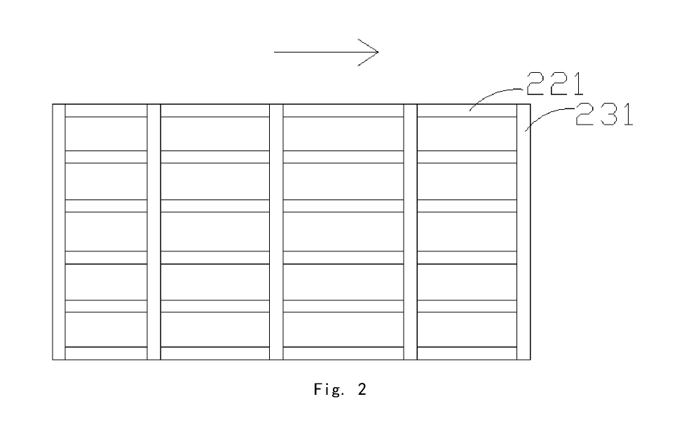

Referring to FIGS. 1 and 2, a first embodiment of the present application provides a flexible circuit board 100, which comprises a substrate 1 and a protective layer 2. The protective layer 2 is disposed on the substrate 1, and the protective layer 2 may be disposed on a single side of the substrate 1. The protection layer 2 may also be disposed on two opposite sides of the substrate 1, so as to get a better protection effect for the substrate 1. The protective layer 2 includes a glue layer 21, a first functional layer 22, and a second functional layer 23 that are sequentially stacked on the substrate 1. The first functional layer 22 includes two or more first bending bands 221 disposed at intervals. The two or more first bending bands 221 extend in a same direction. The second functional layer 23 includes two or more second bending bands 231. The two or more second bending bands 231 extend in a same direction. The extending direction of the two or more first bending bands 221 is at an angle to the extending direction of the second bending band 231. The number and width of the first bending band 221 and the second bending band 231, a pitch of respective first bending bands 221, and a pitch of respective second bending bands 231 are decided according to the material of the first bending bands 221 and the second bent bands 231.

Since the protective layer 2 having the glue layer 21, the first functional layer 22 and the second functional layer 23 is disposed on the substrate 1 of the flexible circuit board 100, and since the first functional layer 22 and the second functional layer 23 replace a portion of a glue layer 21 used in the prior art, the thickness and the number of the glue layer 21 is reduced and thus a situation of over-glue is prevented. Moreover, due to a reduction of the thickness, the flexible circuit board 100 is easier to be bent, thereby preventing the flexible circuit board 100 from having micro-cracking, circuit breaking or peel off. The extending direction of the two or more first bending bands 221 is set at an angle with the extending direction of the two or more second bending bands 231. When the flexible circuit board 100 is bent, since the first bending band 221 and the second bending band 231 are made of a flexible material, those first bending bands 221 or second bending bands 231 that are near a bending direction and have an smaller angle with the bending direction play a role of facilitating the bending of the flexible circuit board 100, while the other first bending bands 221 or second bending bands 231 play an effect of fixing, protecting and strengthening the flexible circuit board 100. By means of that, a micro cracking or peeling of the flexible circuit board 100 due to insufficient strength during a transportation or use can be prevented.

In the embodiment of the present application, the material of the first bending bands 221 and the second bending bands 231 is a flexible inorganic fiber material and/or a flexible polymer. The first bending bands 221 and the second bending bands 231 thus have certain strength, and characteristic of easy bending.

In the embodiment of the present application, the material of the first bending band 221 and the second bending band 231 may be selected from flexible inorganic fiber materials or flexible polymers. The material of the first bending band 221 is flexible Inorganic fiber material, and the material of the second bending band 231 is flexible polymer. Alternatively, the material of the first bending band 221 is flexible polymer, and the material of the second bending band 231 is flexible inorganic fiber material.

In the embodiment of the present application, the flexible inorganic fiber material includes but is not limited to glass fiber, ceramic fiber or carbon fiber. The flexible polymer includes but is not limited to PET, PMMA or non-woven fabric. The material of the glue layer includes UV glue or Tuffy glue, but not limited thereto.

In the embodiment of the present application, the angle formed by the extending direction of the first bending band 221 and the extending direction of the second bending band 231 is 45°˜90°. Preferably, the angle formed by the extending direction of the first bending band 221 and the extending direction of the second bending band 231 is 45°, 60° or 90°. Specifically, in an embodiment of the present application, the angle formed by the extending direction of the first bending band 221 and the extending direction of the second bending band 231 is 90°.

In the embodiment of the present application, in the process of bending the flexible circuit board 100, the bending direction of the first bending band 221 or the bending direction of the second bending band 231 is the same as that of the substrate 1. Preferably, the bending direction of the first bending band 221 is the same as the bending direction of the substrate 1, or the bending direction of the second bending band 231 is the same as the bending direction of the substrate 1.

Preferably, when the bending direction of the first bending band 221 is the same as the bending direction of the substrate 1, the extending direction of the second bending band 231 and the extending direction of the first bending band 221 are perpendicular to each other. Or, when the bending direction of the second bending band 231 is the same as the bending direction of the substrate 1, the extending direction of the first bending band 221 and the extending direction of the second bending band 231 are perpendicular to each other. When the flexible circuit board is bent, the first bending band 221 or the second bending band 231 which has the same bending direction with the flexible circuit board, is easier to be bent due to it replaces portion of the glue layer 21. Meanwhile, the other layer can have an effect of fixing the first bending band 221 or the second bending band 231 that has the same bending direction with the flexible circuit board. By means of that, the strength of the flexible circuit board 100 is improved and the flexible circuit board 100 is effectively protected.

In the embodiment of the present application, the substrate 1 includes a bending region 11, and the protective layer 2 is disposed on the bending region 11. When a bending occurs at the bending region 11, the protective layer 2 can make the bending region more easily bent than the prior art, meanwhile enhance the strength of the bending region 11 so as to get a better protection on the bending region 11.

In the embodiment of the present application, the substrate 1 further includes a bonding region 12 for bonding the panel and connecting the flexible circuit board 100 to the panel. The area of the protection layer 2 is larger than the area of the bending region 11. The protection layer 2 extends from the bending region 11 to the bonding region 12. The protective layer 2 is disposed on the bending region 11 and the bonding region 12. Preferably, the surfaces of the first bending band 221 and the second bending band 231 have an adhesive material, so that the protective layer 2 in the bonding region 12 can be firmly bonded to the panel.

In the embodiment of the present application, the numbers of the first functional layer 22 and the number of the second functional layer 23 are both at least two. When the materials of the first bending band 221 of the first functional layer 22 and the second bending band 231 of the second functional layer 23 have high toughness or low strength, it is preferable that the number of the first functional layer 22 and the number of the second functional layer 23 are both two or three. In this way, the strength of the protective layer 2 can be increased or the bending performance can meet user requirement.

The second aspect of the present invention provides a display panel comprising a flexible circuit board 100 as provided by the first aspect of the present invention. The flexible circuit board 100 can be bent more easily, and prevent the circuit from being damaged. The flexible circuit board 100 is thus effectively protected and the quality of the display panel can be improved.

Specifically, in an embodiment of the present application, the flexible circuit board 100 includes a substrate 1 and a protection layer 2. The substrate 1 is divided into a bending region 11 and a bonding region 12. The protection layer 2 includes a UV glue layer 21, a first functional layer 22, and a second functional layer 23 sequentially disposed on the bending region 11 and the bonding region 12. The first functional layer 22 is formed by six first bending bands 221 disposed at intervals. The extending direction and the bending direction of the first bending bands 221 are the same as the bending direction of the substrate 1 (as shown in FIG. 2). The first bending band 221 is made of glass fiber. The second functional layer 23 is formed by five second bending bands 231 arranged at intervals. The extending direction of the second bending band 231 and the extending direction of the first bending band 221 are perpendicular to each other. The second bending band 231 is made of non-woven fabric. When the flexible circuit board is bent, the first bending band 221 is bent under the force, while the second bending band 231 increases the strength of the flexible circuit board 100 while fixing the first bending band 221.

The foregoing contents are detailed description of the flexible circuit board and the display panel in conjunction with specific preferred embodiments of the present invention. The principles and implementation manners of the present application are described herein. The above description of the embodiments is merely used to help understand the method and core idea of the present application. Meanwhile, those skilled in the art can make changes to the specific implementation manners and the application scope according to the idea of the present application. In view of the foregoing, the content of the specification should not be construed as limiting the present invention.

What is claimed is:

1. A flexible circuit board comprising a substrate and a protective layer, the protective layer being disposed on the substrate, wherein
the protective layer includes a glue layer, a first functional layer, and a second functional layer sequentially stacked on the substrate, the first functional layer includes two or more first bending bands arranged at intervals, the two or more first bending bands extend in the same direction, the second functional layer includes two or more second bending bands arranged at intervals, the two or more second bending bands extend in the same direction, and the extending direction of the two or more first bending bands is disposed with an angle with the extending direction of the two or more second bending bands.

2. The flexible circuit board as claimed in claim 1, wherein the materials of the two or more first bending bands and the two or more second bending bands are flexible inorganic fiber material and/or flexible polymer.

3. The flexible circuit board as claimed in claim 2, wherein the flexible inorganic fiber material includes glass fiber, ceramic fiber or carbon fiber.

4. The flexible circuit board as claimed in claim 2, wherein the flexible polymer includes PET, PMMA or non-woven fabric.

5. The flexible circuit board as claimed in claim 1, wherein an angle formed by the extending direction of the first bending bands and the extending direction of the second bending bands ranges from 45° to 90°.

6. The flexible circuit board as claimed in claim 1, wherein during a process of bending the flexible circuit board, the bending direction of the first bending bands or the bending direction of the second bending bands is the same as the bending direction of the substrate.

7. The flexible circuit board as claimed in claim 1, wherein the substrate includes a bending region, and the protective layer is disposed on the bending region.

8. The flexible circuit board as claimed in claim 7, wherein the substrate further includes a bonding region for bonding a panel, the area of the protection layer is larger than the area of the bending region, and the protection layer extends from the bending region to the bonding region.

9. The flexible circuit board as claimed in claim 1, wherein the number of the first functional layer and the number of the second functional layer are both at least two.

10. A display panel comprising a flexible circuit board which comprises a substrate and a protective layer, the protective layer being disposed on the substrate, wherein
the protective layer includes a glue layer, a first functional layer, and a second functional layer sequentially stacked on the substrate, the first functional layer includes two or more first bending bands arranged at intervals, the two or more first bending bands extend in the same direction, the second functional layer includes two or more second bending bands arranged at intervals, the two or more second bending bands extend in the same direction, and the extending direction of the two or more first bending bands is disposed with an angle with the extending direction of the two or more second bending bands.

11. The flexible circuit board as claimed in claim 10, wherein the materials of the two or more first bending bands and the two or more second bending bands are flexible inorganic fiber material and/or flexible polymer.

12. The flexible circuit board as claimed in claim 11, wherein the flexible inorganic fiber material includes glass fiber, ceramic fiber or carbon fiber.

13. The flexible circuit board as claimed in claim 11, wherein the flexible polymer includes PET, PMMA or non-woven fabric.

14. The flexible circuit board as claimed in claim 10, wherein an angle formed by the extending direction of the first bending bands and the extending direction of the second bending bands ranges from 45° to 90°.

15. The flexible circuit board as claimed in claim 10, wherein during a process of bending the flexible circuit board, the bending direction of the first bending bands or the bending direction of the second bending bands is the same as the bending direction of the substrate.

16. The flexible circuit board as claimed in claim 10, wherein the substrate includes a bending region, and the protective layer is disposed on the bending region.

17. The flexible circuit board as claimed in claim 16, wherein the substrate further includes a bonding region for bonding a panel, the area of the protection layer is larger than the area of the bending region, and the protection layer extends from the bending region to the bonding region.

18. The flexible circuit board as claimed in claim 10, wherein the number of the first functional layer and the number of the second functional layer are both at least two.
